(19) United States
(12) Patent Application Publication
(10) Pub. No.: US 2016/0278206 A1
(43) Pub. Date: Sep. 22, 2016

(54) PRINTED CIRCUIT BOARD

(71) Applicant: SIERRA CIRCUITS, INC., Saratogo, CA (US)

(72) Inventors: Kenneth S. Bahl, Saratoga, CA (US); Konstantine Karavakis, Pleasanton, CA (US)

(21) Appl. No.: 15/165,458

(22) Filed: May 26, 2016

Related U.S. Application Data
(63) Continuation-in-part of application No. 14/281,631, filed on May 19, 2014, now Pat. No. 9,380,700.
Application No. 14/281,631 is a continuation-in-part of application No. 14/297,516, filed on Jun. 5, 2014.

(51) Int. Cl. H05K 1/03; H05K 3/40; H05K 3/18; H05K 3/00; H05K 1/11; H05K 1/09

(52) U.S. Cl. CPC H05K 1/0366; H05K 1/115; H05K 1/09; H05K 3/187; H05K 3/0032; H05K 3/0047; H05K 3/4038; H05K 2201/0154; H05K 2201/015

(57) ABSTRACT

A printed circuit board includes a laminate substrate. The laminate substrate includes catalytic material that resists metal plating except where a surface of the catalytic material is ablated. Metal traces are formed within in trace channels within the laminate substrate. The channels extend below the surface of the catalytic material.

### BACKGROUND

In a typical printed circuit board (PCB) fabrication process, copper clad laminate with copper on both sides of the PCB can be used. A photoimagable resist is applied on both sides of the PCB and exposed and developed to create the circuitry. The unwanted copper between the circuitry is then removed using copper chemical etching solutions. The resist is then chemically removed. For multilayer constructions, glass reinforced not fully cured resin prepregs can be placed on both sides of a finished core and laminated under heat, vacuum and pressure using copper foil on both sides of the PCB. Hole formation can be performed using mechanical means such as drilling or lasers to create blind vias to interconnect the outer layers to the inner ones. Prepregs, if not already impregnated with a synthetic resin, can be reinforced with a synthetic resin. The vias are plated with electroless copper followed by resist which is exposed and developed to form the traces. Cu is plated in the exposed areas and then a copper protective metal such as tin is plated followed by copper etch, resist and tin strip to isolate the traces.

### BRIEF DESCRIPTION OF THE DRAWINGS

FIG. 1 shows a simplified diagram illustrated a printed circuit board structure with embedded traces in accordance with an implementation.

FIG. 2 sets out a simplified flowchart that summarizes a process for fabricating a printed circuit board with embedded traces in accordance with an implementation.

FIG. 3, FIG. 4, FIG. 5, FIG. 6, FIG. 7, FIG. 8, FIG. 9 and FIG. 10 illustrate steps in a process for fabricating a printed circuit board with embedded traces in accordance with an implementation.

FIG. 11 sets out a simplified flowchart that summarizes a process for fabricating a printed circuit board with vias in accordance with an implementation.

FIG. 12, FIG. 13 and FIG. 14 illustrate steps in a process for fabricating a printed circuit board with embedded traces in accordance with an implementation.

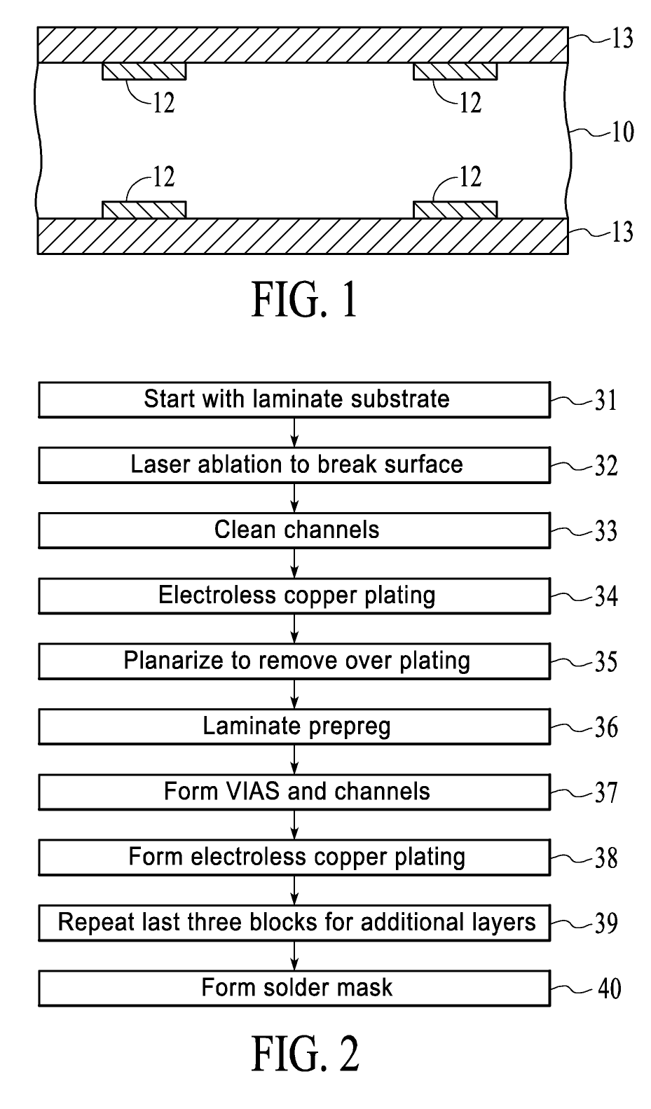

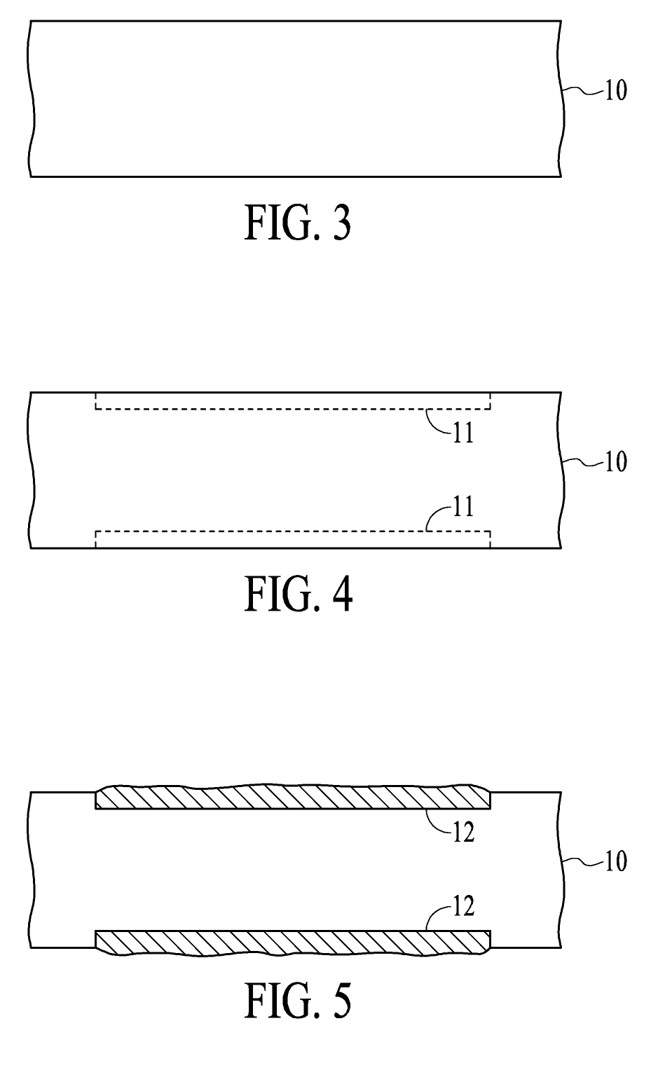

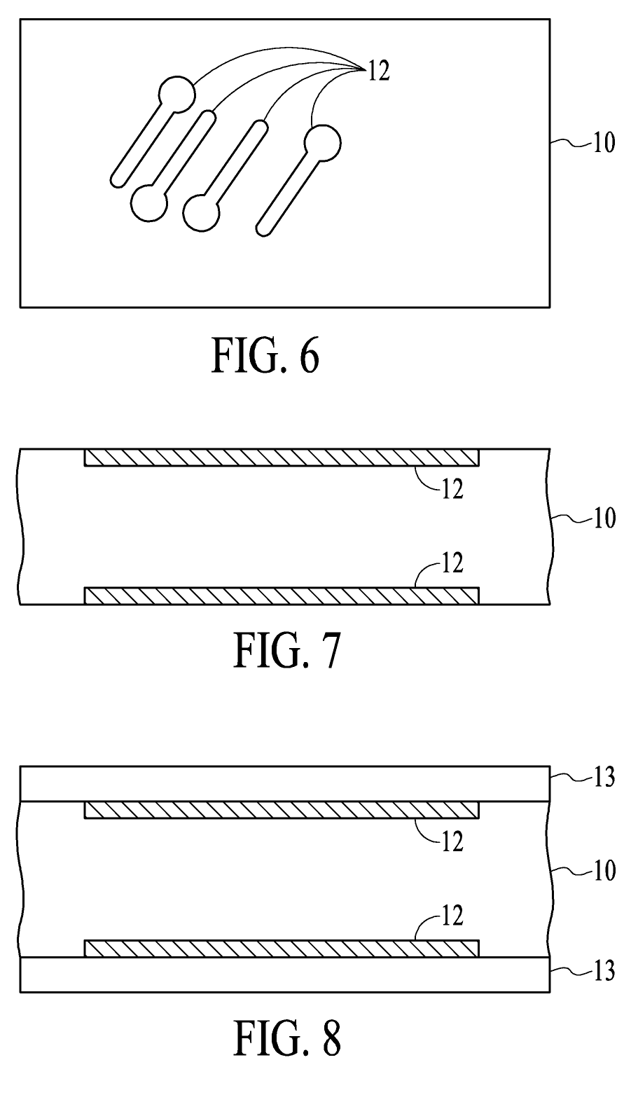

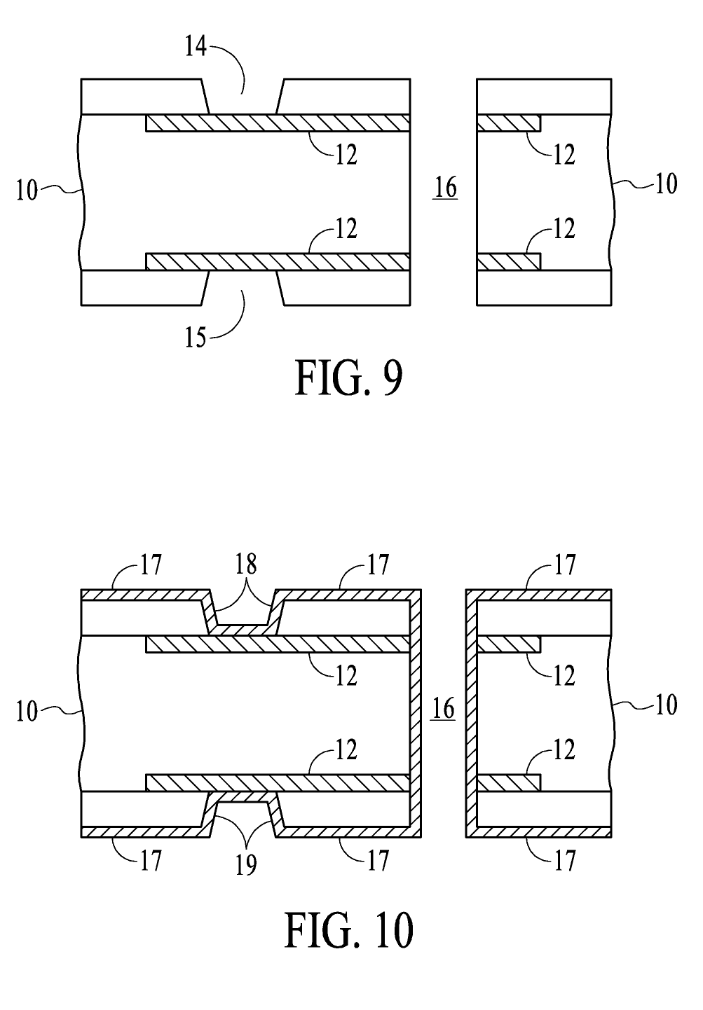

### DESCRIPTION OF THE EMBODIMENT

In printed circuit board (PCB) fabrication where traces are formed above a laminate surface by 0.5-2.5 mils, there is a potential that voids can be entrapped between the traces during a prepreg lamination or during a solder mask application if the PCB is a two-layer board or has more than two layers. In addition, signal integrity and conductor impedance are functions of the dielectric spacing between traces. When PCB traces are formed above a laminate surface, dielectric space above the PCB traces will vary across the length and width of the board. This makes it difficult to accurately control impedance of the PCB traces. Also, when PCB traces are formed above a laminate surface and trace widths and spaces are less than one mil, failures of fine trace lines to properly adhere to the laminate surface can cause both poor yields in fabrication and reliability issues. For example, when forming traces on the substrate surface, the geometry of the traces can vary across the length of the traces due to inaccuracies introduced by the limitations of photolithography and chemical copper etching. Varying geometries of traces can create poor signal propagation and trace impedance.

In order to solve the above issues that arise when PCB traces are formed above a laminate surface, PCB traces are embedded in a laminate substrate so that the PCB traces do not extend above the laminate surface. This is illustrated in FIG. 2 where PCB traces 12 are embedded within a laminate substrate 10. Laminate substrate 10 is composed of, for example, glass or non-glass reinforced catalytic laminate. For example, a non-glass reinforced catalytic substrates can be composed of polyimide, Teflon, cyanate ester, or some other non-glass reinforced catalytic material. A next layer 13 can be, for example, a solder mask for a two-layer PCB board, or a prepreg lamination layer for a PCB board that includes more than two-layers or a non-glass reinforced catalytic adhesive. For example, a prepreg lamination layer can be composed of glass or non-glass reinforced catalytic prepreg.

PCB traces 12 are formed in channels with a depth, for example, between 0.25 and 2.5 mils. The channels are ablated in the surface of laminate substrate 10. Embedding PCB traces 12 provides for better electrical performance since the geometry of the PCB traces is very well controlled by the channel formation process. Also, embedding PCB traces 12 in laminate substrate 10 solves the adhesion problem that arises when traces are very fine, for example, when trace thickness and space between traces is less than one mil. When PCB traces are embedded they are constrained on three sides by laminate surfaces.

FIG. 2 sets out a simplified flowchart that summarizes a process for fabricating a printed circuit board with embedded traces. In a block 31, the process starts with a laminate substrate. For example, a catalytic base laminate is used without any copper. For example, the catalytic base laminate uses palladium powder that includes palladium catalytic particles made out of inorganic fillers primarily Kaolin. For example, the inorganic fillers are produced by contacting a salt palladium, at the surface of a filler such as aluminum silicate, and clays such as Kaolin with a reducing agent. Alternatively, instead of salt of palladium, salt of another metal such as silver can be used.

Hydrazine hydrate can be used as a reducing agent to reduce the palladium salt to palladium metal. The filler can be added into a mixing tank with water in a form of slurry and then a palladium chlorine (PdCI) and hydrochloric acid (HCl) solution added into the mixture followed by the hydrazine hydrate. For more information on making such a catalytic power, see U.S. Pat. No. 4,287,253.

The catalytic powder can be dispersed in an epoxy resin well. The epoxy resin with the catalytic filler in it can be used to impregnate a glass cloth with resin and catalyst using conventional glass cloth coating and drying equipment. The coated semi-cured resin/glass cloths can be used to make laminates for printed circuit boards by pressing the coated semi-cured resin/glass cloths together under standard vacuum laminating equipment. The resulting layered laminate material can be used as a catalytic laminate substrate for a printed circuit board.

For example, laminate substrate 10 is a catalytic laminate substrate of any thickness between, for example, two and sixty mils. For example, laminate substrate 10 is composed of a non-clad catalytic base laminate with outside prepregs that are resin rich so that after vacuum lamination the resulting finished laminate has a resin rich surface. For example, resin rich prepregs can have (but are not limited to) a glass style 106 with 71% resin content or a glass style 1035 with 65% resin content. Using a resin rich laminate surface assures that when channels are made, primarily resin is removed and not glass. This can speed up the channel formation process and improve the quality of the channel. For example, the surface of the resin rich catalytic laminate is initially protected with a release film so that the surface is protected from scratches as scratches will plate up copper and create defects. When ready for channel formation, the release film is removed from both sides of laminate substrate 10.

In a block 32, laser ablation is used to break the surface of laminate substrate 10 and form channels 11, as shown in FIG. 4. The laser ablation can be accomplished, for example, with an ultraviolet (UV) excimer laser, with an Yttrium aluminum garnet (YAG) laser, with a UV YAG laser or with some other type of laser, or alternatively, a non-laser ablation process. Excimer laser ablation creates good depth control and channel resolution.

As an alternative to using laser ablation to break the surface and form channels, resist can be applied on both sides of laminate substrate 10. The resist is exposed and developed to delineate locations of the channels. For example, resist thickness is thicker than the depth of the channels. For example, for a channel depth of 0.5 mils, resist thickness can be 1.0 to 1.5 mils. The formation of the channels can then be performed using plasma etching with a combination of gasses (e.g., O2, CF4, Ar, etc.) along with the proper power and duration. It is expected the channel will be etched at a different rate than the resist. For example, the resist thickness should be sufficiently thicker that the channel depth so that when the channel depth is reached there is some resist left protecting unexposed regions of the surfaces of laminate substrate 10. After plasma etching, the remaining resist can be removed by a resist stripper.

Alternatively, instead of protecting the surface of laminate substrate with resist when performing plasma etch, other protective material can be used. For example, the protection can be accomplished using a foil, such as a copper foil or aluminum foil, that gets applied to laminate substrate 10. The shiny side of the foil can be placed facing laminate substrate 10 so the foil can be peeled off after channel formation. For example, after applying the foil to laminate substrate 10, resist will be applied over the foil. The resist is exposed/develop to expose the foil over the channel regions. The foil is etched to expose the channel regions in laminate substrate 10. The remaining resist is then stripped and the channels are plasma etched. The remaining foil is peeled off and processing continues.

Alternatively, channels can be formed using high pressure water cutting. The high pressure water cutting can be performed using programmable high pressure water cutting machines such as those used for cutting hard materials such as steel and stainless steel. Another mechanical processes such as drilling and routing can be used for making the channels.

As previously described, the resin rich surface of the catalytic substrate is broken in the process of forming channels which expose the underlying catalytic material. The resin rich surface may be broken using any of the methods previously described, including laser ablation, plasma etching with use of a resist, plasma etching with use of a foil, plasma etching with use of a foil and photoresist, high pressure water cutting, drilling, or routing.

In a block 33, the laminate substrate is cleaned to remove debris from channels 11. For example, the cleaning can be accomplished by an ultrasonic rinse using acoustic wave with a frequency within the range of 40 to 160 megahertz (MHz). A more aggressive chemical cleaning is typically not used as an aggressive chemical cleaning may result in the surface of laminate substrate 10 being roughened or etched. If the surface of laminate substrate 10 is etched this can result in metal plating at locations not within formed channels.

In a block 34, traces 12 are formed in channels 11, as illustrated by FIG. 5. For example, traces 12 are a metal such as copper. For example, to form copper traces, laminate substrate 10 is immersed into a fast electroless copper bath. Channels 11 are plated all the way up and slightly above the surface of laminate substrate 10. The electroless copper bath plates only on the exposed catalytic areas that were exposed by the ablation process. No copper plates outside channels 11 since during the lamination process of making laminate substrate 10 the copper catalyzes only at locations where the surface of the laminate substrate 10 where the surface is ablated, scratched or roughened. As a result, copper traces form where ablation has penetrated the surface of laminate substrate 10. A simplified top view of traces within laminate substrate 10 is shown in FIG. 6.

In a block 35, the surfaces of laminate substrate 10 are planarized, for example, using fine grid sandpaper (e.g., 420 grit to 1200 grit). The planarization removes any excess copper that extends above the channels. For example, a planarization machine such as those produced by MASS, Inc., can be used. The resulting planarization is illustrated in FIG. 7. For a two-layer PCB board, a solder mask is applied. For example, the PCB may be finished by performing selective gold plating followed by singulation and inspection.

When the PCB board will have more than two layers, in a block 36, a resin rich catalytic prepreg material 13 is laminated on both sides of laminate substrate. For example, a release film such as tedlar or Teflon is used. The result is shown in FIG. 8. Alternative to using resin rich catalytic prepreg material 13, another material can be used such as a catalytic adhesive material implemented, for example, as a layer of non-glass reinforced catalytic adhesive.

In a block 37, blind and through vias are formed, for example by use of laser or mechanical means such as a drill. Channels are also formed. The result is illustrated by FIG. 9 where a blind via 14, a blind via 15 and a through via 16 are shown.

After an ultrasonic cleaning in water, in a block 38, traces 17 are formed. For example, traces 17 are a metal, such as copper. The process of forming vias by mechanical drilling or laser drilling assists in exposing catalytic particles on the hole wall. Because of the exposure of catalytic particles on the hole walls, electroless copper will plate on the hole walls allowing for copper plating on the hole walls through the entirety of the formed via. The copper plating provides electrical continuity through the resulting vias. For example, traces 17 are formed by electroless copper plating. The electroless copper plating will result in traces being formed within vias 14, 15 and 16, as illustrated by trace regions 18, 19 and 20, respectively. This results in the four-layer board structure shown in FIG. 10. For example, the PCB may be finished by performing processing steps such as applying a solder mask, selective gold plating, singulation (i.e., depaneling from an array) and inspection.

Alternatively, in a block 39, additional layers may be added by repeating blocks 36, 37 and 38 as often as necessary to reach the desired numbers of layers. When the desired numbers of layers are reached, in a block 40, the PCB may be finished by performing such processing steps such as applying a solder mask, selective gold plating, singulation (i.e., depaneling PCBs from an array) and inspection.

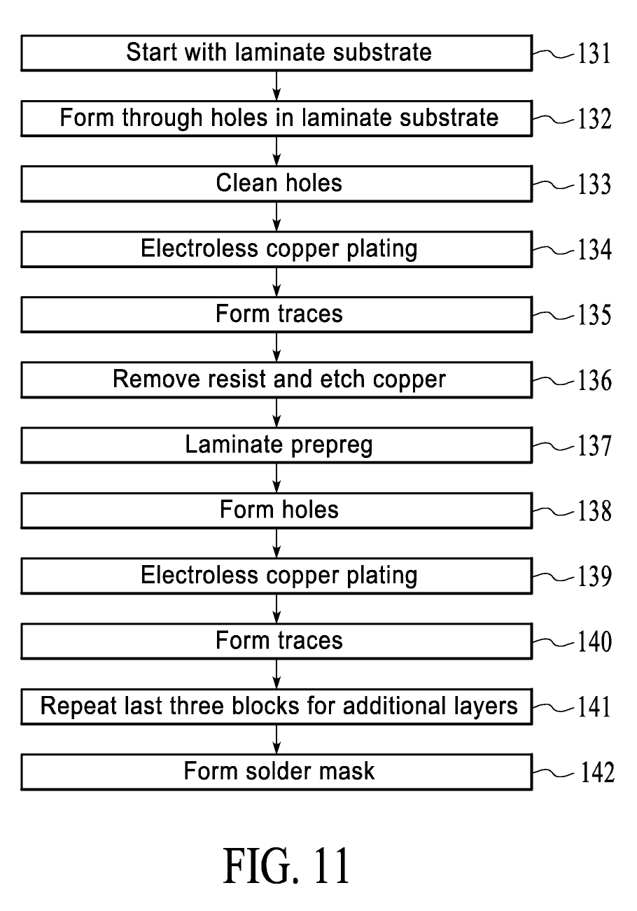

FIG. 11 sets out a simplified flowchart that summarizes a process for forming vias in a printed circuit board. This may be done, for example, immediately before the forming of traces. In a block 131, the process starts with a laminate substrate similar to formation of laminate substrate 10 described in block 31 above. The laminate substrate has catalytic particles dispersed in it. For example, the catalytic particles are made of inorganic filler (kaolin, silicon dioxide, etc.) with Palladium (Pd) or other metal adsorbed on the surface of the inorganic filler particles that cause metal such as electroless copper to plate on them. The surface of the laminate can have copper on both sides. The copper thickness can be as low as 0.1 micron and up to a few microns or more.

In a block 132, through holes for the vias are formed in the laminate substrate, for example by drilling, laser, or some other process capable of forming a hole through a laminate substrate. In a block 133, the holes are cleaned to remove debris. For example, the cleaning can be accomplished by plasma, an ultrasonic rinse or some other cleaning process. The drilling process exposes the catalytic particles so that when the laminate gets bathed in an electroless copper bath, the copper will plate on the hole wall. Since the catalytic particles are part of the laminate, the standard chemical cleaning methods, such as desmear and catalytic activation of the hole wall, used for making PCBs the conventional way are not needed.

In a block 134, electroless copper plating is performed so that the hole walls and the surface of both sides of the PCB are plated with copper. Because the drilling or other process used to form holes exposes catalytic particles of the laminate substrate on the hole walls, copper from the electroless copper bath plates on the hole wall. In block 135, resist is applied on both sides of the laminate substrate. The resist is exposed and developed to form traces and pads. Copper is then plated in the exposed traces and pads followed by an etch protective coating such as tin. Copper thickness on the surface of the laminate substrate and on the hole wall, for example, can be as low as 0.1 mil or as high as 3 mils or more.

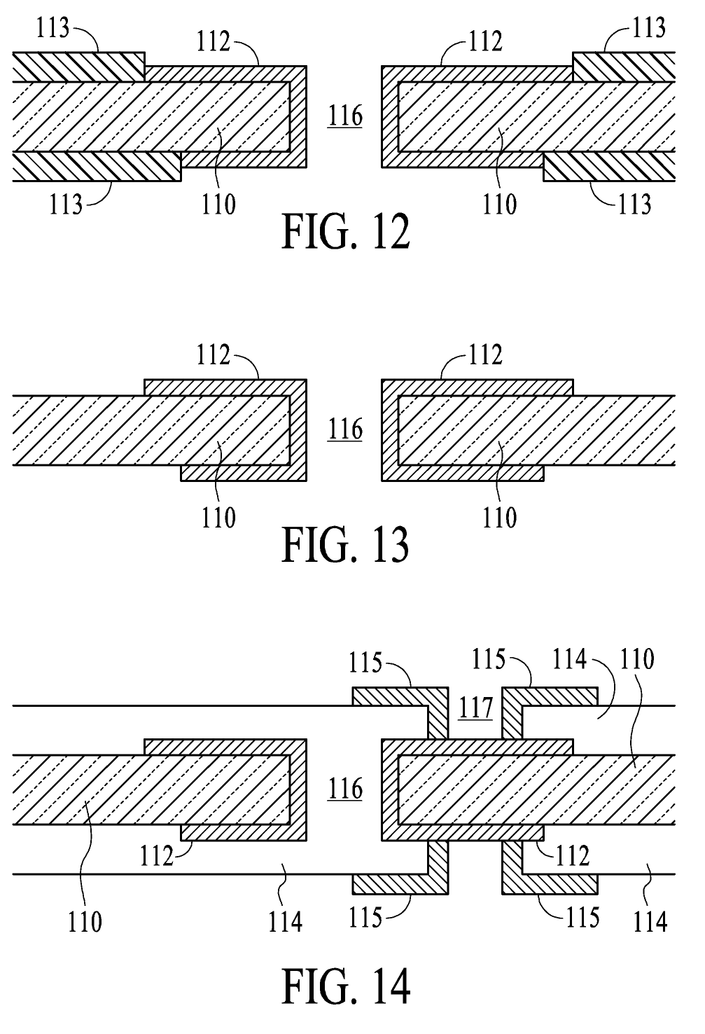

FIG. 12 shows the result of the processing. A copper layer 112 has been formed on a laminate substrate 110. Copper layer 112 extends through a hole 116 to join with traces on both a top side and a bottom side of laminate substrate 110. A patterned resist layer 113 determines the pattern of the traces and pads on both sides of laminate substrate 110.

In a step 136 resist is removed and an etch process to remove and thin the surface of the copper traces and remove any unwanted features. The result is shown in FIG. 13. For example, the PCB may be finished by performing selective gold plating followed by singulation and inspection.

When the PCB board will have more than two layers, in a block 137, a resin rich catalytic prepreg material 114 is laminated on both sides of laminate substrate 110. For example, a release film such as tedlar or Teflon is used. Alternative to using resin rich catalytic prepreg material 114, another material can be used such as a catalytic adhesive material implemented, for example, as a layer of non-glass reinforced catalytic adhesive. For example, layers are formed by bonding catalytic glass or non-glass reinforced resin on both sides with thin copper foil or by adding thin copper on the surface using copper sputtering or vapor deposition techniques.

In a block 138, holes for blind and through vias are formed, for example by use of laser or mechanical means such as a drill. After cleaning, for example, by an ultrasonic cleaning in water. In a block 139, electroless copper plating is performed to complete vias in the holes. In block 140, traces are formed. For example, resist is applied on both sides of the laminate substrate. The resist is exposed and developed to form traces and pads. Copper is then plated in the exposed traces and pads followed by an etch protective coating such as tin.

FIG. 14 shows a resulting blind via 117 having been form as a result of the electroless copper plating within the hole. Via 117 allows traces 115 to be connected to traces 112. For example, the resulting four-layer board structure shown in FIG. 14 PCB may be finished by performing processing steps such as applying a solder mask, selective gold plating, singulation (i.e., depaneling from an array) and inspection.

As represented by a block 141, additional layers may be added by repeating blocks 137, 138, 139 and 140 as often as necessary to reach the desired numbers of layers. When the desired numbers of layers are reached, in a block 142, the PCB may be finished by performing such processing steps such as applying a solder mask, selective gold plating, singulation (i.e., depaneling PCBs from an array) and inspection.

In an alternative implementation, the process described above can be performed with the exception that blocks 132 and 133 are omitted. That is, starting with the laminate substrate, in block 134, traces are formed by applying resist expose and developing the traces and pads that need to stay on the substrate. After electroless copper plating in block 135, the copper on the exposed areas is chemically etched, followed by stripping the resist in block 136. In block 137, prepreg is applied on both sides. The process then continues to block 138, as outlined in FIG. 11.

The foregoing discussion discloses and describes merely exemplary methods and embodiments. As will be understood by those familiar with the art, the disclosed subject matter may be embodied in other specific forms without departing from the spirit or characteristics thereof. Accordingly, the present disclosure is intended to be illustrative, but not limiting, of the scope of the invention, which is set forth in the following claims.

What is claimed is:

1. A printed circuit board, comprising:
a laminate substrate, the laminate substrate comprising resin and catalytic material reinforced with glass or non-glass material so that the laminate substrate resists metal plating except where a surface of the catalytic material is broken; and,
metal traces within trace channels formed within the laminate substrate, the channels extending below the surface of the catalytic material, so that the surface under the metal traces is broken allowing the metal traces to plate on the laminate surface.

2. A printed circuit board as in claim 1, additionally comprising:
additional catalytic material over the laminate substrate;
vias through the additional catalytic material; and,
additional traces on the surface of the catalytic material, including traces within the vias.

3. A printed circuit board as in claim 2 wherein the additional catalytic material is composed of one of the following:
resin rich catalytic prepreg material;
catalytic adhesive material.

4. A printed circuit board as in claim 1 wherein the laminate substrate includes palladium catalytic particles.

5. A printed circuit board as in claim 1 wherein the laminate substrate includes a catalytic powder dispersed in an epoxy resin well.

6. A printed circuit board as in claim 1 additionally comprising,
vias that extend completely through the laminate substrate, each via including copper plating on walls of a hole formed in the laminate substrate where the surface of the catalytic material has been broken so that metal plates to exposed catalytic material on the walls of the hole.

7. A printed circuit board as in claim 1, wherein the laminate substrate comprises a glass cloth impregnated with the resin and the catalytic material.

8. A printed circuit board as in claim 1, wherein the laminate substrate is a non-glass reinforced catalytic substrate composed of polyimide, Teflon or cyanate ester.

9. A printed circuit board, comprising:
a laminate substrate, the laminate substrate comprising resin and catalytic material reinforced with glass or non-glass material so that the laminate substrate resists metal plating except where a surface of the catalytic material is broken; and,
vias that extend completely through the laminate substrate, each via including metal plating on walls of a hole formed in the laminate substrate where the surface of the catalytic material has broken so that metal plates to exposed catalytic material on the walls of the hole.

10. A printed circuit board as in claim 9, additionally comprising:
additional catalytic material over the laminate substrate;
additional vias through the additional catalytic material; and,
additional traces on the surface of the catalytic material, including traces within the additional vias.

11. A printed circuit board as in claim 10 wherein catalytic material is composed of one of the following:
resin rich catalytic prepreg material;
catalytic adhesive material.

12. A printed circuit board as in claim 9 wherein the laminate substrate includes palladium catalytic particles.

13. A printed circuit board as in claim 9 wherein the laminate substrate includes a catalytic powder dispersed in an epoxy resin well.

14. A printed circuit board as in claim 9, wherein the laminate substrate comprises a glass cloth impregnated with the resin and the catalytic material.

15. A printed circuit board as in claim 9, wherein the laminate substrate is a non-glass reinforced catalytic substrate composed of polyimide, Teflon or cyanate ester.

16. A method for making a printed circuit board, comprising:
forming a laminate substrate with resin and catalytic material reinforced with glass or non-glass material so that the laminate substrate resists metal plating except where a surface of the catalytic material is broken;
forming holes that extend completely through the laminate substrate, wherein the catalytic material resists copper plating except where a surface of the catalytic material is broken, and wherein the holes break the surface of the catalytic material so that walls of the holes do not resist copper plating;
forming trace paths on the laminate substrate, the surface of the catalytic material being broken at locations of the trace paths on the laminate substrate; and,
performing an electroless copper bath process to place copper traces within the trace paths and within the hole.

17. A method as in claim 16 wherein holes are formed by one of the following:
laser;
drilling.

18. A method as in claim 16, additionally comprising:
laminating a resin rich catalytic prepreg material on the laminate substrate;
forming vias; and,
forming additional traces on the surface of the resin rich catalytic prepreg material, including forming traces within the vias.

19. A method as in claim 16, wherein the laminate substrate is composed of a non-clad catalytic base laminate with outside prepregs that are resin rich so that after vacuum lamination the resulting finished laminate has a resin rich surface.

20. A method as in claim 16, wherein the laminate substrate is a non-glass reinforced catalytic substrate composed of polyimide, Teflon or cyanate ester.
